(19) United States
(12) Patent Application Publication
(10) Pub. No.: US 2024/0145466 A1
(43) Pub. Date: May 2, 2024

(54) BIPOLAR JUNCTION TRANSISTOR STRUCTURES

(71) Applicant: Taiwan Semiconductor Manufacturing Co., Ltd., Hsinchu (TW)

(72) Inventor: Zi-Ang SU, Taoyuan County (TW)

(73) Assignee: Taiwan Semiconductor Manufacturing Co., Ltd., Hsinchu (TW)

(21) Appl. No.: 18/186,512

(22) Filed: Mar. 20, 2023

Related U.S. Application Data
(60) Provisional application No. 63/381,835, filed on Nov. 1, 2022.

(51) Int. Cl. H01L 27/082; H01L 29/15; H01L 29/66; H01L 29/735

(52) U.S. Cl. CPC H01L 27/082; H01L 29/151; H01L 29/6625; H01L 29/735

(57) ABSTRACT

Bipolar junction transistors (BJTs) are disclosed that are formed on a superlattice structure of stacked silicon and silicon germanium layers. The superlattice structure can be implanted with ions to form emitter, base, and collector regions of the BJTs. Altering width ratios of the implanted emitter, base, and collector regions can tune BJT performance. The BJTs can be implemented in a Darlington circuit configuration.

### CROSS-REFERENCE TO RELATED APPLICATIONS

This application claims the benefit of U.S. Provisional Application No. 63/381,835, filed on Nov. 1, 2022, titled “Bipolar Junction Transistor Structures,” which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (FinFETs), and bipolar junction transistors (BJTs). Such scaling down has increased the complexity of semiconductor manufacturing processes.

### BRIEF DESCRIPTION OF THE DRAWINGS

Aspects of the present disclosure are best understood from the following detailed description when read with the accompanying figures. It is noted that, in accordance with common practice in the industry, various features are not drawn to scale. In fact, the dimensions of the various features may be arbitrarily increased or reduced for clarity of discussion.

FIGS. 1A and 1B are top plan views and cross-sectional views of bipolar junction transistors, in accordance with some embodiments of the present disclosure.

FIG. 2 is a flow diagram of a method for fabricating bipolar junction transistors shown in FIGS. 1A and 1B, in accordance with some embodiments of the present disclosure.

FIGS. 3A, 3B, 4A, 4B, 5A, 5B, 6A, 6B, and 7 are top plan views and cross-sectional views of the bipolar junction transistors shown in FIGS. 1A and 1B at various stages of their fabrication process, in accordance with some embodiments of the present disclosure.

FIG. 8 is a circuit schematic of a Darlington circuit, in accordance with some embodiments of the present disclosure.

FIGS. 9 and 10 are cross-sectional and top plan views of P-N-P bipolar junction transistors in a Darlington circuit configuration, in accordance with some embodiments of the present disclosure.

FIG. 11 is a circuit schematic of a Darlington circuit, in accordance with some embodiments of the present disclosure.

FIGS. 12 and 13 are cross-sectional and top plan views of N-P-N bipolar junction transistors in a Darlington circuit configuration, in accordance with some embodiments of the present disclosure.

### DETAILED DESCRIPTION

The following disclosure provides different embodiments, or examples, for implementing different features of the provided subject matter. Specific examples of components and arrangements are described below to simplify the present disclosure. These are, of course, merely examples and are not intended to be limiting. For example, the formation of a first feature on a second feature in the description that follows may include embodiments in which the first and second features are formed in direct contact, and may also include embodiments in which additional features may be formed that are between the first and second features, such that the first and second features are not in direct contact.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments of the present disclosure, the terms “about” and “substantially” can indicate a value of a given quantity that varies within 20% of the value (for example, ±1%, 2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

Bipolar junction transistors are used in integrated circuits to implement high power devices, such as high voltage switches, high current switches, analog circuits, and radio frequency (RF) signal amplifiers for use in wireless applications (e.g., cell phones and mobile computing). Low-power devices used in logic and memory applications can be implemented as field effect transistors, such as MOSFETs. Bipolar junction transistors have been manufactured along with planar, or 2-D, FETs (e.g., MOSFETs or complimentary MOSFETs) in a hybrid process known as BiCMOS. With the advent of FinFETs and gate all-around FETS (GAAFETs), there arises a need for a manufacturing process in which these 3-D FETs can be fabricated on a shared substrate along with bipolar junction transistors. The structures and methods described herein use ion implantation to form emitter, base, and collector regions within a silicon (Si)/silicon germanium (SiGe) stack that is compatible with a GAAFET process.

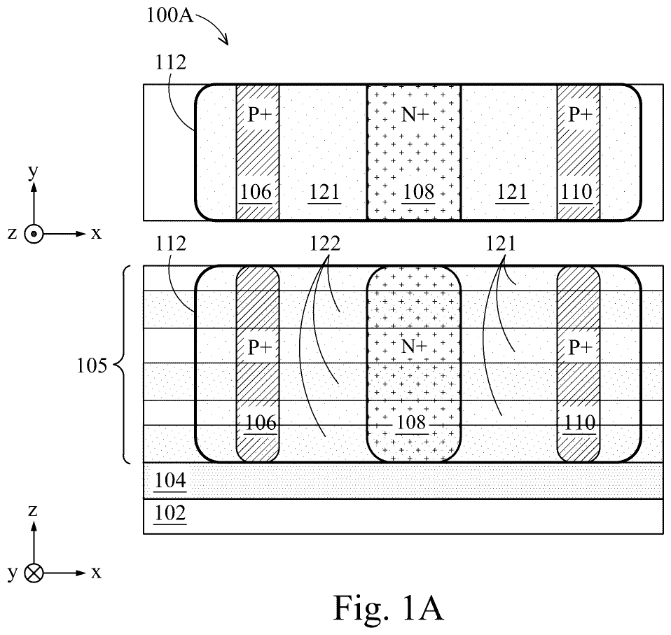

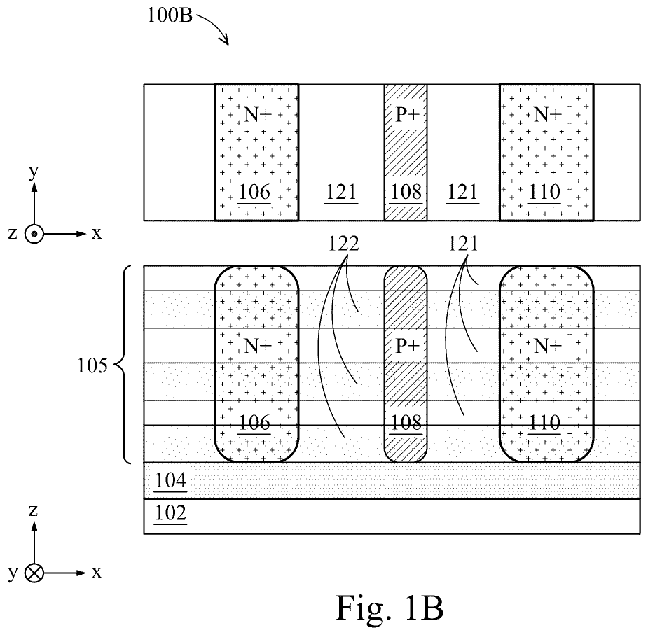

FIGS. 1A and 1B show implementations of P-N-P and N-P-N bipolar junction transistors, respectively, as formed on a Si/SiGe stack, according to some embodiments of the present disclosure. The upper panel of FIG. 1A shows a top plan view of a top surface of a P-N-P bipolar junction transistor 100A. The upper panel of FIG. 1B shows a top plan view of a top surface of an N-P-N bipolar junction transistor 100B. The lower panel of FIG. 1A shows a corresponding cross-sectional view of P-N-P bipolar junction transistor 100A. The lower panel of FIG. 1B shows a corresponding cross-sectional view of N-P-N bipolar junction transistor 100B.

P-N-P bipolar junction transistor 100A and N-P-N bipolar junction transistor 100B can be formed side-by-side on the same substrate 102. A dielectric layer 104 can be deposited on substrate 102, followed by a superlattice structure 105. P-N-P bipolar junction transistor 100A and N-P-N bipolar junction transistor 100B each include an emitter 106, a base 108, and a collector 110 that are formed by an implantation of dopants into superlattice structure 105. P-N-P bipolar junction transistor 100A further includes an n-well 112, formed by implanting n-type dopants into superlattice structure 105. Emitter 106, base 108, and collector 110 of P-N-P bipolar junction transistor 100A are disposed in n-well 112. In some embodiments of the present disclosure, emitter 106, base 108, and collector 110 of N-P-N bipolar junction transistor 100B are not disposed in a well structure.

In some embodiments of the present disclosure, superlattice structure 105 can be formed as an alternating stack of nanostructured Si layers 121 and nanostructured SiGe layers 122. Superlattice structure 105 located in one area of substrate 102 can be used to form one or more GAAFETs, while superlattice structure 105 located in another area of substrate 102 can be used to form one or more bipolar junction transistors. The two areas of superlattice structure 105 bearing GAAFETs and bipolar junction transistors can be adjacent to one another on substrate 102, separated from one another in different regions of the same integrated circuit (IC) chip, or on different IC chips formed on substrate 102. Formation of emitter, base, and collector regions 106, 108, and 110, respectively, of bipolar junction transistors within superlattice structure 105 will be described below in more detail.

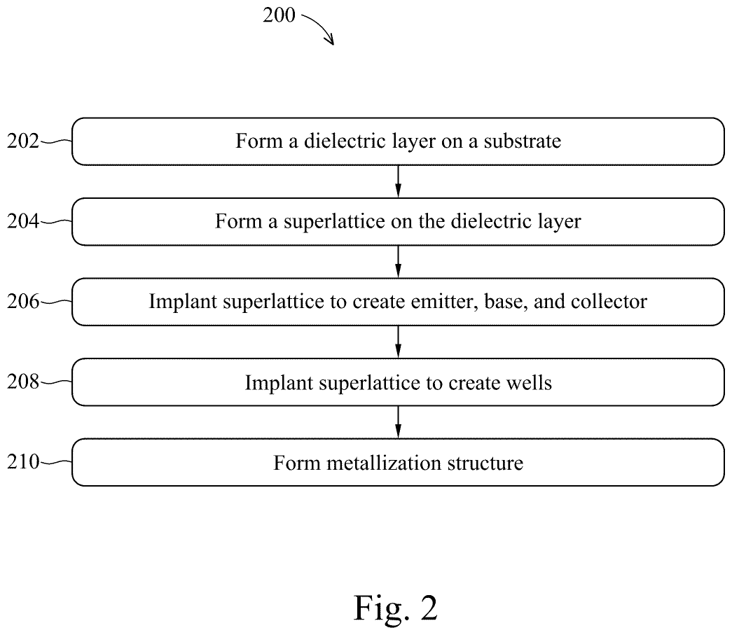

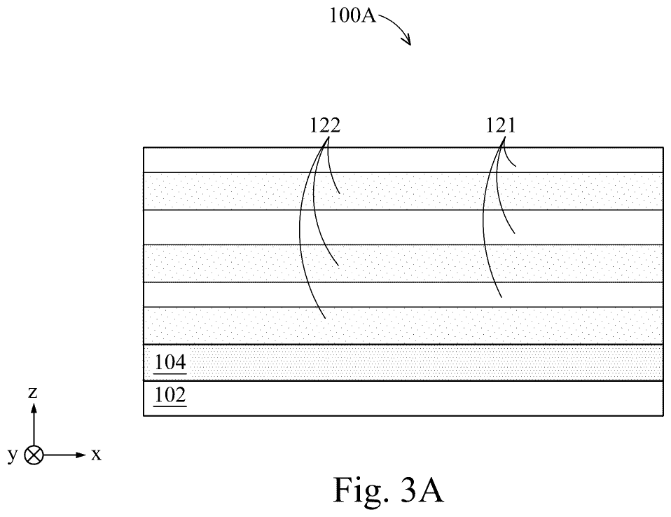

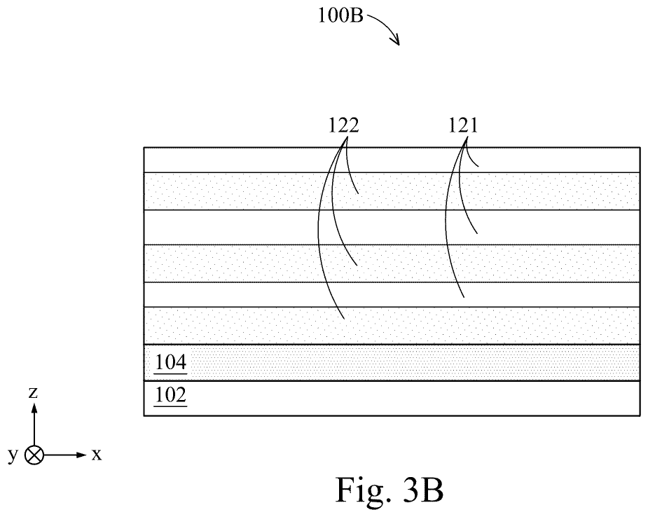

FIG. 2 illustrates a method 200 for fabricating bipolar junction transistors 100A and 100B on substrate 102, according to some embodiments of the present disclosure. For illustrative purposes, operations illustrated in FIG. 2 will be described with reference to processes for fabricating bipolar junction transistors 100A and 100B as illustrated in FIGS. 3A, 3B, 4A, 4B, 5A, 5B, 6A, 6B, and 7, which are cross-sectional views and top plan views of bipolar junction transistors 100A and 100B at various stages of their fabrication, according to some embodiments. Operations of method 200 can be performed in a different order, or not performed, depending on specific applications. It is noted that method 200 may not produce a complete bipolar junction transistor. Accordingly, it is understood that additional processes can be provided before, during, or after method 200, and that some of these additional processes may be briefly described herein.

Referring to FIG. 2, in operation 202, dielectric layer 104 can be formed on substrate 102 as shown in FIGS. 3A and 3B with respect to bipolar junction transistors 100A and 100B, according to some embodiments of the present disclosure.

As used herein, the term “substrate” describes a material onto which subsequent material layers are added. The substrate may be patterned. Materials added to the substrate may be patterned or may remain unpatterned. Substrate 102 can be a bulk semiconductor wafer or the top semiconductor layer of a semiconductor-on-insulator (SOI) wafer (not shown), such as silicon-on-insulator. In some embodiments of the present disclosure, substrate 102 can include a crystalline semiconductor layer with its top surface parallel to a (100), (110), (111), or c-(0001) crystal plane. Alternatively, substrate 102 may be made from an electrically non-conductive material, such as a glass or sapphire wafer, or a plastic substrate. Substrate 102 can include one or more of a wide array of semiconductor materials such as, but not limited to, silicon (Si). In some embodiments of the present disclosure, substrate 102 can include (i) an elemental semiconductor, such as germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Further, substrate 102 can be doped with p-type dopants (e.g., boron (B), indium (In), aluminum (Al), or gallium (Ga)) or n-type dopants (e.g., phosphorus (P) or arsenic (As)). In some embodiments of the present disclosure, different portions of substrate 102 can have opposite type dopants.

In some embodiments of the present disclosure, dielectric layer 104 can include one or more of silicon nitride (SiN), silicon dioxide (SiO₂), carbon-doped SiO₂, silicon oxynitride (SiON), silicon carbide (SiC), silicon carbo-nitride (SiCN), tetraethoxysilane (TEOS), a low-k dielectric such as fluorosilicate glass (FSG), or a spin-on dielectric such as hydrogen silsesquioxane (HSQ) and methyl silsesquioxane (MSQ), and combinations thereof. In some embodiments of the present disclosure, dielectric layer 104 can be formed using chemical vapor deposition (CVD), low pressure chemical vapor deposition (LPCVD), plasma enhanced CVD (PECVD), high density plasma chemical vapor deposition (HDP-CVD), flowable chemical vapor deposition (FCVD), atomic layer deposition (ALD), electron beam evaporation, physical vapor deposition (PVD), spin coating, or any other suitable deposition process at a thickness between about 50 nm and about 70 nm. In some embodiments, dielectric layer 104 can be a composite of multiple layers, such as a silicon layer having a thickness of about 50 nm silicon layer and a dielectric layer having a thickness of about 10 nm.

Referring to FIG. 2, in operation 204, superlattice structure 105 can be formed on dielectric layer 104 as shown in FIGS. 3A and 3B with respect to bipolar junction transistors 100A and 100B, according to some embodiments of the present disclosure.

Superlattice structure 105 can include a stack of nanostructured layers 121 and 122 arranged in an alternating configuration. In some embodiments of the present disclosure, nanostructured layers 121 include materials similar to one another, e.g., epitaxial Si, and nanostructured layers 122 include materials similar to one another, e.g., epitaxial SiGe. Although FIGS. 3A and 3B show three nanostructured Si layers 121 and three nanostructured SiGe layers 122, any number of nanostructured layers can be included in each superlattice structure 105. The alternating configuration of superlattice structure 105 can be achieved by alternating deposition, or epitaxial growth, of SiGe and Si layers, starting with SiGe on dielectric layer 104. Si layers can form nanostructured layers 121, which are interleaved with SiGe nanostructured layers 122. Each of the nanostructured layers 121-122 may have thicknesses in the range of about 1 to about 5 nm. In some embodiments of the present disclosure, the topmost nanostructured layers (e.g., Si layers) of superlattice structure 105 can be thicker than the underlying nanostructured layers.

The stack of two different semiconductor layers making up superlattice structure 105 can be formed via an epitaxial growth process after forming the first nanostructured layer 122 on dielectric layer 104. The epitaxial growth process can include (i) chemical vapor deposition (CVD), such as low pressure CVD (LPCVD), rapid thermal chemical vapor deposition (RTCVD), metal-organic chemical vapor deposition (MOCVD), atomic layer CVD (ALCVD), ultrahigh vacuum CVD (UHVCVD), reduced pressure CVD (RPCVD), and other suitable CVD processes; (ii) molecular beam epitaxy (MBE) processes (iii) another suitable epitaxial process; or (iv) a combination thereof. In some embodiments of the present disclosure, nanostructured layers 121 and 122 can be grown by an epitaxial deposition/partial etch process, which repeats the epitaxial deposition/partial etch process at least once. Such repeated deposition/partial etch process is also called a “cyclic deposition-etch (CDE) process.” In some embodiments of the present disclosure, nanostructured layers 121 and 122 can be grown by a selective epitaxial growth (SEG) process, where an etching gas can be added to promote selective growth on exposed semiconductor surfaces of substrate 102 or nanostructured layers 121 and 122, but not directly on insulating material (e.g., the material of dielectric layer 104).

Superlattice structure 105 can be doped in-situ by introducing one or more precursors during the above-noted epitaxial growth process. For example, the stack of two different semiconductor layers can be in-situ p-type doped during the epitaxial growth process using p-type doping precursors, such as diborane (B₂H₆) and boron trifluoride (BF₃). In some embodiments of the present disclosure, the stack of two different semiconductor layers can be in-situ n-type doped during an epitaxial growth process using n-type doping precursors, such as phosphine (PH₃) and arsine (AsH₃).

In some embodiments of the present disclosure, the term “p-type” defines a structure, layer, and/or region as being doped with, for example, boron (B), indium (In), or gallium (Ga). In some embodiments of the present disclosure, the term “n-type” defines a structure, layer, and/or region as being doped with, for example, phosphorus (P) or arsenic (As).

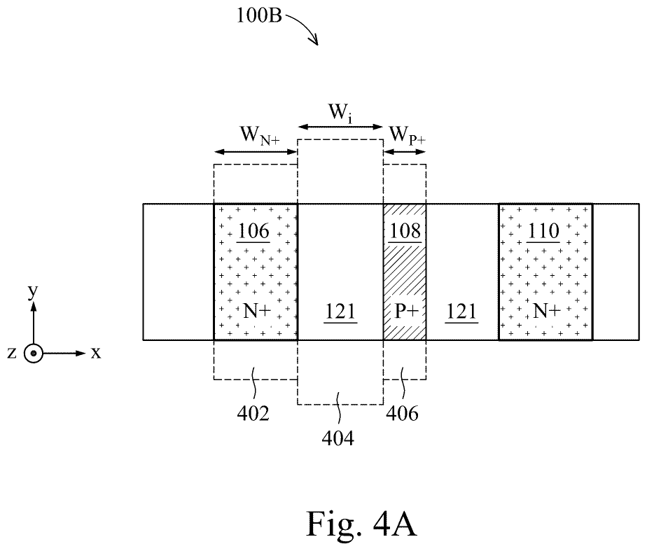

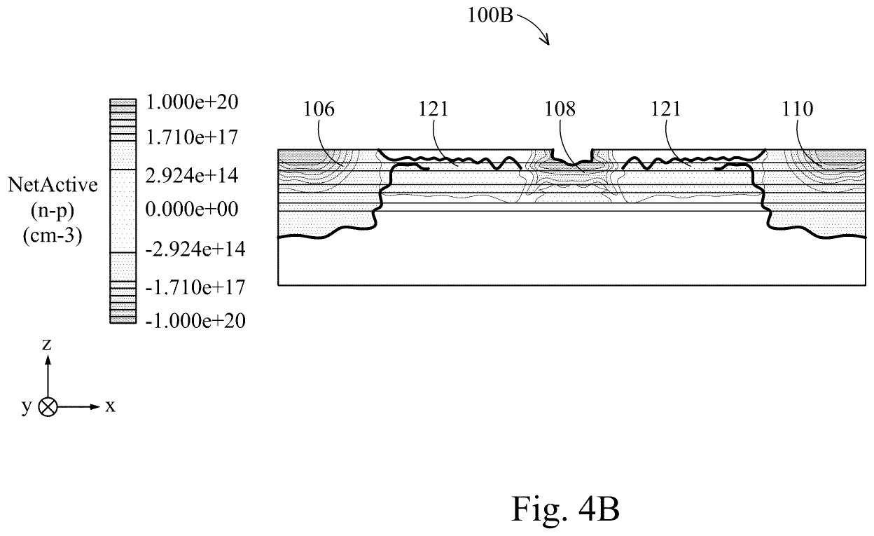

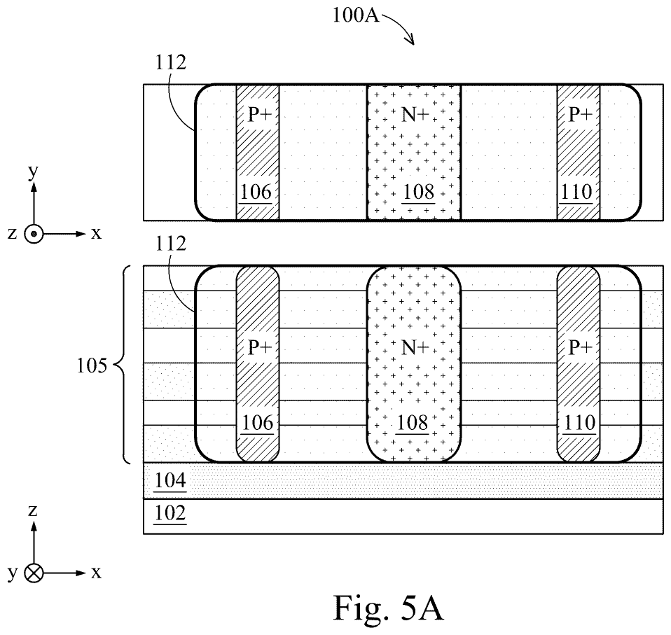

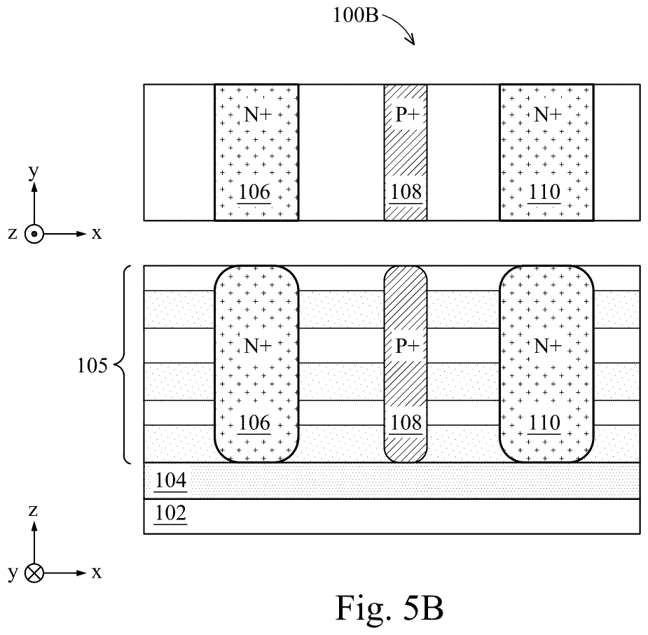

Referring to FIG. 2, in operation 206, superlattice structure 105 can be doped to form emitter, base, and collector regions, according to some embodiments of the present disclosure. Doping of superlattice structure 105 can be accomplished by ion implantation through a mask as shown in FIGS. 4A, 4B, and 5B with respect to bipolar junction transistor 100B, and FIGS. 5A and 5B with respect to bipolar junction transistors 100A and 100B. In some embodiments of the present disclosure, superlattice structure 105 can be doped after it is fully formed, instead of, or in addition to, being doped in-situ during deposition of nanostructured layers 121 and 122. An anneal operation can follow the doping operation to repair damage to the surrounding crystal lattice.

FIG. 4A reproduces the top plan view of N-P-N bipolar junction transistor 100B shown in the upper panel of FIG. 1B, with the addition of thee photoresist mask areas: N+ mask area 402, isolation mask area 404, and P+ mask area 406. Isolation mask area 404 separates N+ mask area 402 from P+ mask area 406. Each mask area is associated with a corresponding implant width W_{N+}, Wᵢ, and W_{P+} as shown in FIG. 4A. Implant width W_{N+} is the width of N+ mask area 402 through which negative ions are implanted into superlattice structure 105 to form emitter and collector regions 106 and 110, respectively; implant width W_{P+} is the width of P+ mask area 406 through which positive ions are implanted into superlattice structure 105 to form base 108; and implant width W1 is the width of isolation mask area 404 through which no implantation occurs into superlattice structure 105.

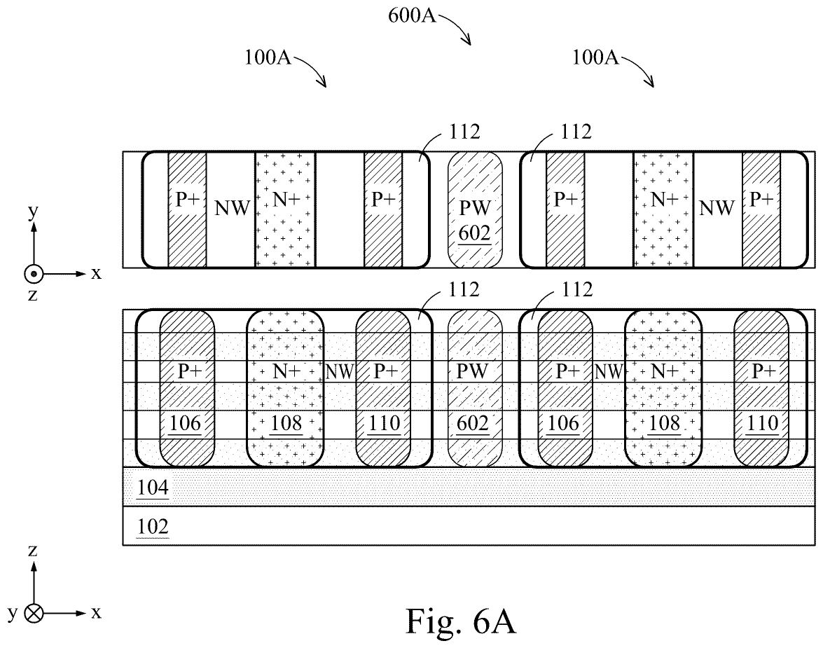

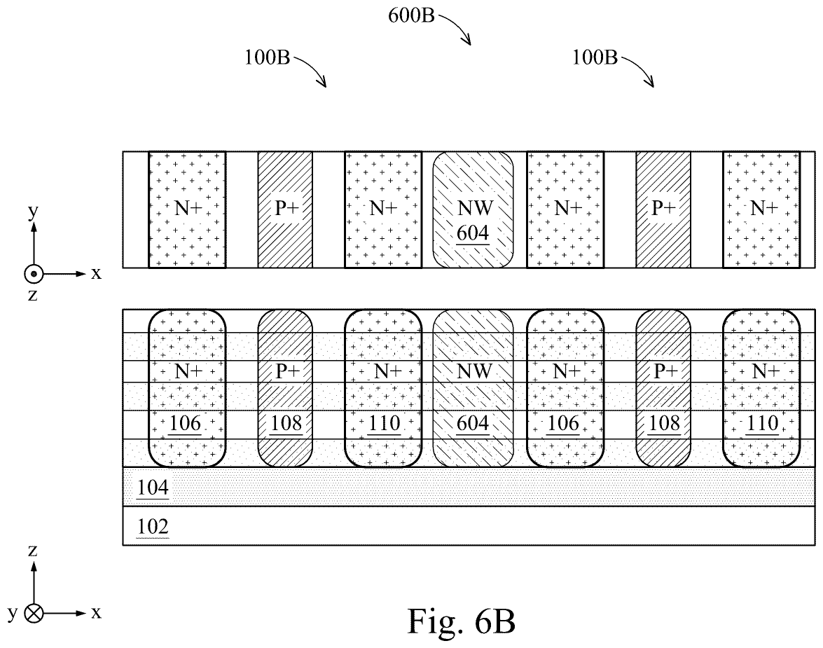

P-well and n-well regions, shown in FIGS. 5A and 6A, can be formed in a similar way by implanting superlattice structure 105 using photoresist masks designed for well implants as described below. Wells occupy larger regions, and are doped with lower ion concentrations than the emitter, base, and collector regions. When wells are present, as in P-N-P bipolar junction transistor 100A, the background concentration of the region Wᵢ between the terminals is substantially equal to the concentration of the well implant.

Referring to FIG. 4A, in some embodiments of the present disclosure, a ratio of implant widths W_{N+}:Wᵢ:W_{P+} can be in a range of about 4:3:1 to about 6:2:1. In some embodiments of the present disclosure, regions of the superlattice structure that are implanted with n-type dopants can be wider than regions of the superlattice structure that are implanted with p-type dopants. In some embodiments of the present disclosure, the undoped regions Wᵢ between terminals of the bipolar junction transistors can be about half as wide as the doped regions corresponding to emitter and collector terminals. Referring to FIGS. 4A and 5B, in some embodiments of the present disclosure, a ratio of widths of emitter, base, and collector regions in N-P-N bipolar junction transistor 100B can be about 5:1:5. Referring to FIG. 5A, in some embodiments of the present disclosure, a ratio of widths of emitter, base, and collector regions in P-N-P bipolar junction transistor 100A can be about 1:5:1. The implant width W_{N+} of the emitter region determines the emitter injection rate and the recombination rate, which determine the flow of charge carriers through N-P-N bipolar junction transistor 100B. Consequently, the implant width W_{N+} of emitter 106 directly impacts the overall performance of N-P-N bipolar junction transistor 100B. For example, when N-P-N bipolar junction transistor 100B is used as an amplifier, the implant width ratios W_{N+}:Wᵢ:W_{P+} can determine the gain of the amplifier.

FIG. 4B reproduces a portion of the cross-sectional view of N-P-N bipolar junction transistor 100B shown in the lower panel of FIG. 1B and corresponding to the top plan view shown in FIG. 4A. FIG. 4B includes a superimposed map of ion concentrations in the implanted emitter, base, and collector regions. Emitter 106 and collector 110, which are implanted with n-type dopants, can have negative ion concentrations in a range of about 1.71×10¹⁷ cm⁻³ to about 1.0×10²⁰ cm⁻³. Base 108, which is implanted with p-type dopants, can have positive ion concentrations in a range of about 1.71×10¹⁷ cm⁻³ to about 1.0×10²⁰ cm⁻³. Isolation regions, which are formed as the top nanostructured Si layers 121 between base 108 and each of emitter 106 and collector 110 have substantially zero ion concentrations.

FIGS. 5A and 5B show cross-sectional views of superlattice structure 105 following ion implantation of emitter 106, base 108, and collector 110 regions for both P-N-P bipolar junction transistor 100A and N-P-N bipolar junction transistor 100B. FIG. 5B shows emitter/base/collector implants that have been made using the photoresist masks, N+ mask area 402, isolation mask area 404, and P+ mask area 406, as shown in FIG. 4A. The widths of the photoresist masks W_{N+}, Wᵢ, and W_{P+} define the widths of the implanted regions shown in both the upper and lower panels of FIG. 5B.

Referring to FIG. 2, in operation 208, superlattice structure 105 can be doped further by ion implantation to form doped wells, according to some embodiments of the present disclosure. An N-P-N device may be disposed in a p-type region of substrate 102, or p-well. AP-N-P device may be disposed in an n-type region of substrate 102, or n-well. In some embodiments of the present disclosure, one or both of the bipolar junction transistors 100A and 100B includes a well implant. For example, FIG. 5A shows n-well 112 in which P-N-P bipolar junction transistor 100A is disposed, while there is no well implant surrounding N-P-N bipolar junction transistor 100B. An anneal operation can follow the well implant operations to repair damage to the surrounding crystal lattice.

In some embodiments of the present disclosure, the well implants, e.g., n-well 112, can be completed first, followed by the emitter/base/collector implants, such that operation 208 can be performed first, followed by operation 206. In some embodiments of the present disclosure, well implants are performed in a similar fashion as emitter/base/collector implants, using a photoresist mask as described above. In some embodiments of the present disclosure, N and P ion concentrations of well implants are less than the N+ and P+ ion concentrations of emitter/base/collector implants.

FIGS. 6A and 6B show dual lateral bipolar junction transistors 600A and 600B, respectively, in which superlattice structure 105 has been doped with an n-well, a p-well, and emitter/base/collector implants. A pair of P-N-P bipolar junction transistors 100A forms dual lateral bipolar junction transistor 600A, as shown in FIG. 6A. Similarly, a pair of N-P-N bipolar junction transistors 100B adjacent to one another form dual lateral bipolar junction transistor 600B, as shown in FIG. 6B. In some embodiments of the present disclosure, an implant sequence used to form dual lateral bipolar junction transistors 600A and 600B begins with p-well implants, followed by n-well implants, N+ implants, and P+ implants. Such an implant sequence entails use of four separate implant operations, each using a different photoresist mask. Referring to FIG. 6A, each of the bipolar junction transistors 100A making up dual lateral bipolar junction transistor 600A is disposed in n-well 112. The pair of bipolar junction transistors 100A is separated by a p-well 602. Referring to FIG. 6B, neither one of the bipolar junction transistors 100B making up dual lateral bipolar junction transistor 600B is disposed in a well, but the pair of bipolar junction transistors 100B is separated by an n-well 604.

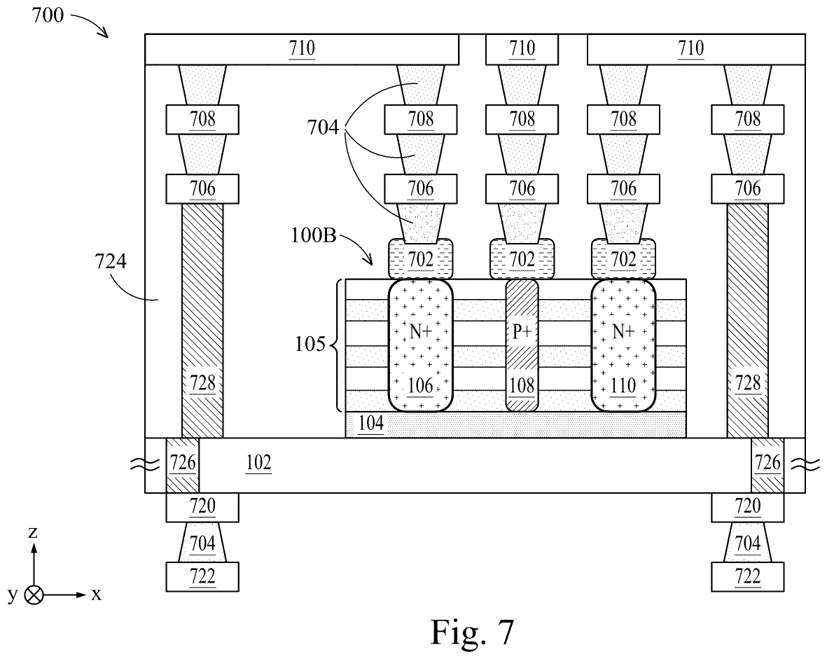

Referring to FIG. 2, in operation 210, a multilayer metallization structure 700 is formed for bipolar junction transistors, with respect to FIG. 7, according to some embodiments of the present disclosure. In some embodiments of the present disclosure, multilayer metallization structure 700 provides connections to bipolar junction transistor 100B, via both front side metal layers and back side metal layers. On a front side of substrate 102, there can be a contact layer 702, vias 704, a first metal layer 706, a second metal layer 708, a third metal layer 710, and so on. In some embodiments, following device formation, substrate 102 is removed so that superlattice structure 105 is positioned over a backside dielectric.

In some embodiments of the present disclosure, back side metallization is used to connect bipolar junction transistor 100B to a pad, for example, by a first backside metal layer 720 and a second backside metal layer 722 coupled by vias 704. Front side and/or back side metal lines can be made of, for example, aluminum, copper, or alloys thereof. Metal layers 706, 708, 710, 720, and 722 can include liners made of, for example, titanium (Ti) and/or titanium nitride (TiN). Multilayer metallization structure 700 can be formed as either a damascene structure or a patterned metal structure, in which metal lines are insulated from one another by an inter-layer dielectric (ILD) 724. Back side metal layers 720 and 722 can be coupled to front side metal layers 706, 708, and 710 using one or both of a through-silicon via (TSV) 726 and a through-oxide via (TOV) 728.

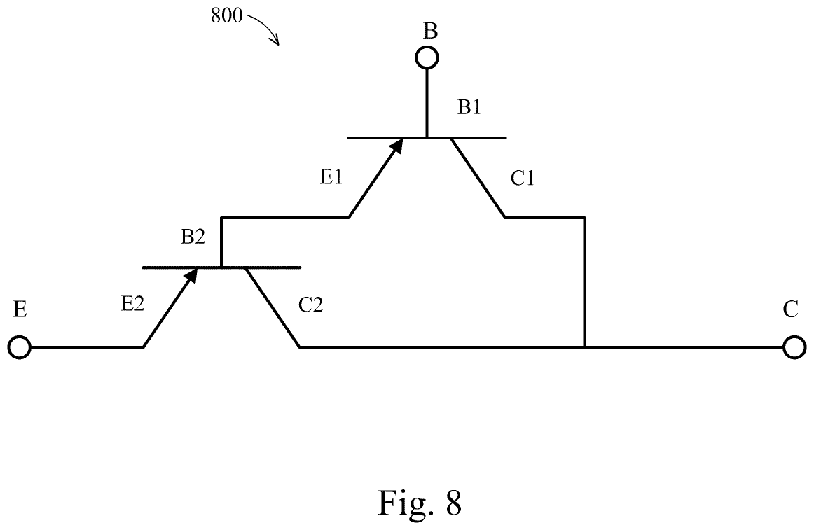

Referring to FIG. 8, a Darlington circuit configuration 800 is formed, according to some embodiments of the present disclosure. In some embodiments of the present disclosure, dual lateral P-N-P bipolar junction transistors 600A can be coupled via multilayer metallization structure 700 to form Darlington circuit configuration 800. A circuit schematic for Darlington circuit configuration 800 made from two P-N-P bipolar junction transistors is shown in FIG. 8, in which the emitter, base, and collector of Darlington circuit configuration 800 are denoted by E, B, and C. The use of P-N-P bipolar junction transistors to form Darlington circuit configuration 800 is signified by the arrows pointing away from the emitter terminals in FIG. 8. Within Darlington circuit configuration 800, the base terminal B1 and the collector terminal C1 of the first P-N-P bipolar junction transistor are coupled to the collector terminal C2 of the second P-N-P bipolar junction transistor, and the emitter terminal μl of the first P-N-P bipolar junction transistor is coupled to the base terminal B2 of the second P-N-P bipolar junction transistor. Therefore, the overall Darlington circuit configuration can have an emitter current equal to that of the second P-N-P bipolar junction transistor, a base current equal to that of the first P-N-P bipolar junction transistor, and a collector current equal to the sum of the two collector currents. The base B of the Darlington circuit of FIG. 8 is coupled to the collector C.

The gain for Darlington circuit configuration 800 is calculated to be 2β+β², where β is the gain for a single bipolar junction transistor. Thus, if β=1 for a single bipolar junction transistor, the gain for Darlington circuit configuration 800 is 3. That is, the gain of two bipolar junction transistors, when coupled in a Darlington circuit configuration is three times that of a single bipolar junction transistor. The gain of a bipolar junction transistor is defined as the ratio of the collector current to the base current, or β=I_{c}/I_{b}. In the Darlington circuit configuration, I_{C} is the sum of the two collector currents, I_{C1} and I_{C2}, and the base current is I_{b1}. Thus, when β₁=β₂=β,

$$\begin{matrix}β = \frac{{I}_{C}}{{I}_{b}} \\ = \frac{{I}_{{C}_{1}} + {I}_{{C}_{2}}}{{I}_{{b}_{1}}} \\ = \frac{{β}_{1} \times {I}_{{b}_{1}} + {β}_{2} \times {I}_{b 2}}{{I}_{{b}_{1}}} \\ = {β}_{1} + {β}_{2} \times \frac{{I}_{b 2}}{{I}_{{b}_{1}}} = {β}_{1} + {β}_{2} \times \frac{( {I}_{{b}_{1}} + {I}_{{c}_{1}} )}{{I}_{b 1} \text{?}} \\ = {β}_{1} + {β}_{2} \times \frac{( {I}_{{b}_{1}} + {β}_{1} \times {I}_{{b}_{1}} )}{{I}_{{b}_{1}}} \\ = {β}_{1} + {β}_{2} + {β}_{1} \times {β}_{2} \\ = 2 β + {β}^{2} .\end{matrix}$$

$$\text{?} \text{indicates text missing or illegible when filed}$$

In some embodiments of the present disclosure, Darlington circuit configuration 800 is implemented as a temperature sensor that has a temperature coefficient, TC, that is two to three times greater, due to the 3× gain of the Darlington circuit configuration. Furthermore, the compact design of dual lateral bipolar junction transistors 600A/600B using ion implantation as described above is particularly suitable for implementation as Darlington circuit configuration 800.

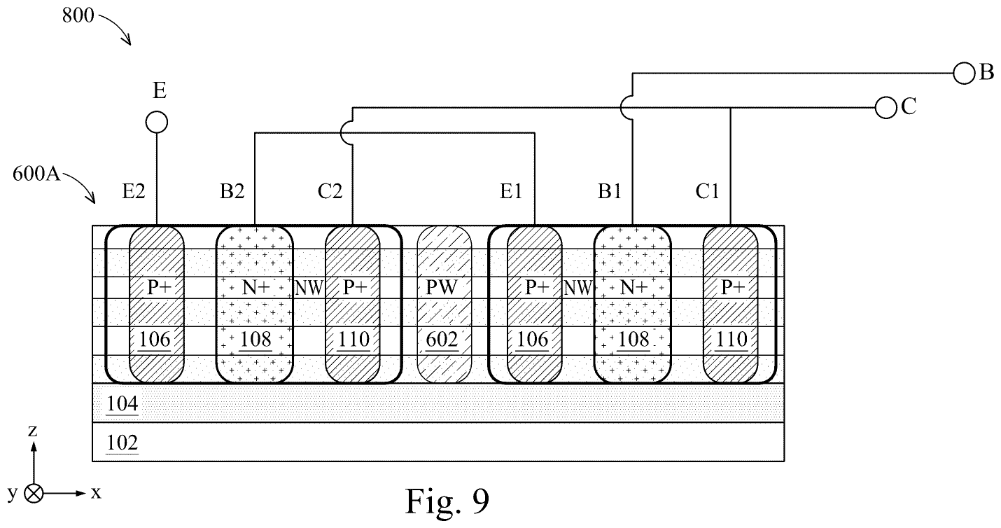

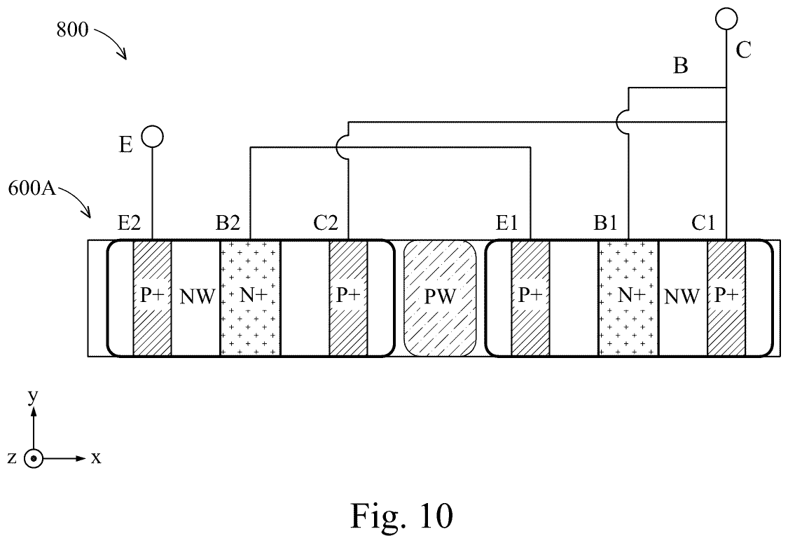

Referring to FIGS. 9 and 10, dual lateral P-N-P bipolar junction transistors 600A are connected in a Darlington circuit configuration 800, according to some embodiments of the present disclosure. FIG. 9 shows how the cross-sectional view of dual lateral P-N-P bipolar junction transistor 600A can be wired as Darlington circuit configuration 800. FIG. 10 shows how the top plan view of dual lateral P-N-P bipolar junction transistors 600A can be wired as Darlington circuit configuration 800. Three connections are made in FIGS. 9 and 10: first, the collector terminals C1 and C2 of the two P-N-P bipolar junction transistors are connected together as the output collector; second, the base of the second P-N-P bipolar junction transistor is coupled to the emitter of the first P-N-P bipolar junction transistor; third, the base B of the Darlington circuit is coupled to the collector C.

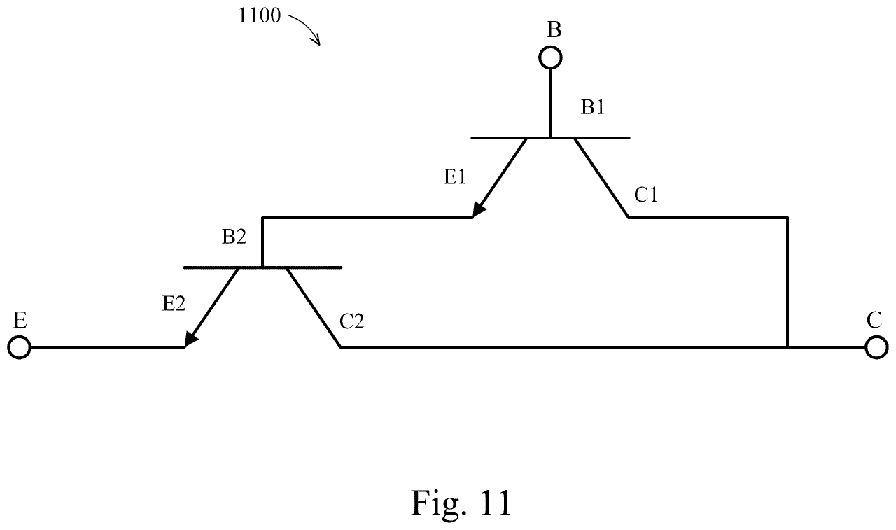

Referring to FIG. 11, a Darlington circuit configuration 1100 is formed, according to some embodiments of the present disclosure. In some embodiments of the present disclosure, dual lateral N-P-N bipolar junction transistors 600B can be coupled via multilayer metallization structure 700 to form Darlington circuit configuration 1100. A circuit schematic for Darlington circuit configuration 1100 made from two N-P-N bipolar junction transistors is shown in FIG. 11, in which the emitter, base, and collector of Darlington circuit configuration 1100 are denoted by E, B, and C. The use of N-P-N bipolar junction transistors to form Darlington circuit configuration 1100 is signified by the arrows pointing toward the emitter terminals in FIG. 11. Within Darlington circuit configuration 1100, the base terminal B1 and the collector terminal C1 of the first N-P-N bipolar junction transistor are coupled to the collector terminal C2 of the second N-P-N bipolar junction transistor, and the emitter terminal μl of the first N-P-N bipolar junction transistor is coupled to the base terminal B2 of the second N-P-N bipolar junction transistor. Therefore, the overall Darlington circuit configuration can have an emitter current equal to that of the second bipolar junction transistor, a base current equal to that of the first N-P-N bipolar junction transistor, and a collector current equal to the sum of the two collector currents. The base B of the Darlington circuit of FIG. 11 is not coupled to the collector C.

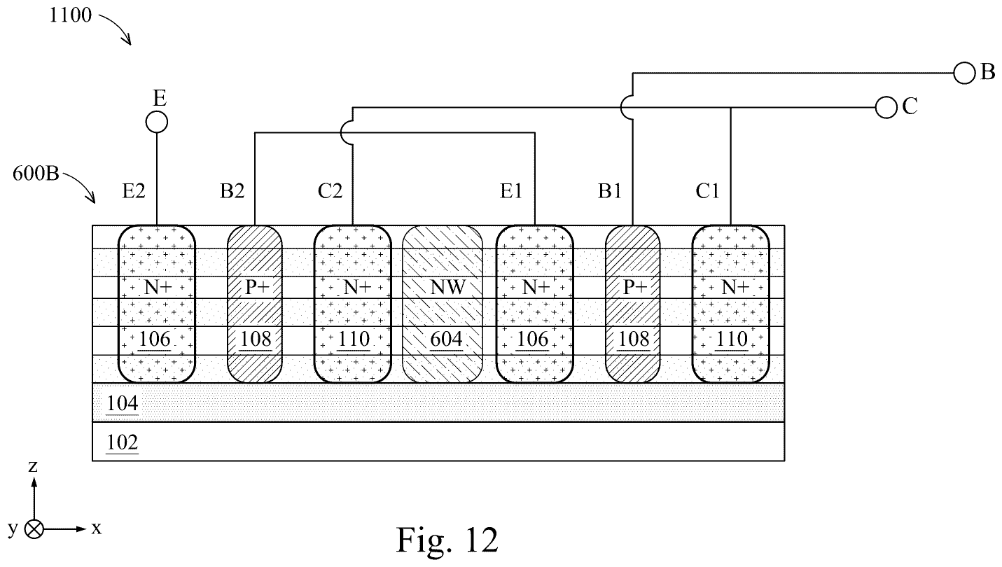

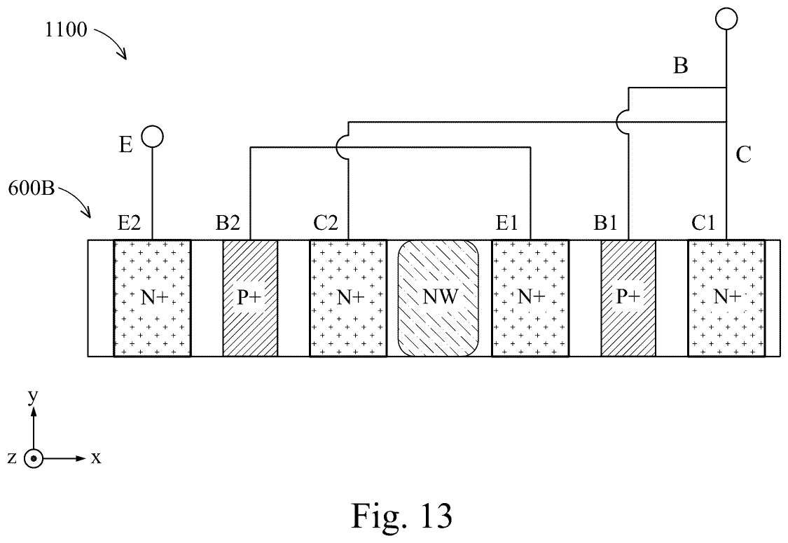

Referring to FIGS. 12 and 13, dual lateral N-P-N bipolar junction transistors 600B are connected in Darlington circuit configuration 1100, according to some embodiments of the present disclosure. FIG. 12 shows how the cross-sectional view of dual lateral N-P-N bipolar junction transistor 600B can be wired as Darlington circuit configuration 1100. FIG. 13 shows how the top plan view of dual lateral N-P-N bipolar junction transistors 600B can be wired as Darlington circuit configuration 1100. Two connections are made in FIGS. 12 and 13: first, the collector terminals C1 and C2 of the two N-P-N bipolar junction transistors are connected together as the output collector; second, the base of the second N-P-N bipolar junction transistor is coupled to the emitter of the first N-P-N bipolar junction transistor. In Darlington circuit configuration 1100, the base B of the Darlington circuit is not coupled to the collector C.

Bipolar junction transistors formed on a superlattice structure of stacked silicon and silicon germanium layers can coexist on the same substrate with GAAFETs. The superlattice structure can be implanted with ions to form wells, and emitter, base, and collector regions of the bipolar junction transistors. Dual N-P-N and P-N-P configurations can be formed with wells separating the pairs of transistors. Altering width ratios of the implanted regions can tune the performance of the devices. The resulting bipolar junction transistors are compact and efficient. Dual bipolar junction transistors formed on the superlattice structure are particularly suitable for use in a Darlington circuit configuration to enhance gain when the transistors are used as amplifiers or sensors.

In some embodiments of the present disclosure, a method includes: forming a dielectric layer on a substrate; forming a superlattice structure on the dielectric layer; implanting selected regions of the superlattice structure with dopants to form emitter, base, and collector regions of a bipolar junction transistor (BJT); and forming a metallization structure on the emitter, base, and collector regions of the BJT.

In some embodiments of the present disclosure, a method includes: forming a dielectric layer on a substrate; forming a superlattice structure on the dielectric layer; implanting selected first regions of the superlattice structure with a first dose of dopants to form wells; implanting selected second regions of the superlattice structure with a second dose of dopants to form emitter, base, and collector terminals of a pair of bipolar junction transistors (BJTs), where the second dose is higher than the first dose; and forming a metallization structure on the emitter, base, and collector terminals of the pair of BJTs.

In some embodiments of the present disclosure, a circuit includes: a first bipolar junction transistor (BJT) formed on a superlattice structure, the first BJT having a first base, a first emitter, and a first collector; and a second BJT formed on the superlattice structure, the second BJT having a second base, a second emitter, and a second collector, where the first emitter is electrically coupled to the second base, and the first and second collectors are electrically coupled to one another.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a dielectric layer on a substrate;
forming a superlattice structure on the dielectric layer;
implanting selected regions of the superlattice structure with dopants to form emitter, base, and collector regions of a bipolar junction transistor (BJT); and
forming a metallization structure on the emitter, base, and collector regions of the BJT.

2. The method of claim 1, wherein forming the superlattice structure comprises forming alternating stacked layers of silicon (Si) and silicon germanium (SiGe).

3. The method of claim 1, further comprising implanting selected other regions of the superlattice structure with dopants at a lower dose than that of dopants in the emitter, base, and collector regions of the BJT.

4. The method of claim 3, wherein implanting the selected other regions comprises implanting an n-well surrounding the BJT.

5. The method of claim 1, wherein implanting the selected regions comprises implanting the selected regions of the superlattice structure with the dopants to form the emitter, base, and collector regions according to a width ratio of about 5:1:5.

6. The method of claim 1, wherein implanting the selected regions comprises implanting the selected regions of the superlattice structure with the dopants to form the emitter, base, and collector regions according to a width ratio of about 1:5:1.

7. The method of claim 1, wherein implanting the selected regions comprises forming undoped regions between terminals of the BJT that are about half as wide as doped regions corresponding to the emitter and collector regions.

8. The method of claim 1, wherein implanting the selected regions comprises implanting the superlattice structure with n-type dopants and p-type-dopants to form n-type regions that are wider than p-type regions.

9. The method of claim 1, wherein forming the metallization structure comprises forming at least one back side metal layer and at least one front side metal layer.

10. A method, comprising:
forming a dielectric layer on a substrate;
forming a superlattice structure on the dielectric layer;
implanting selected first regions of the superlattice structure with a first dose of dopants to form wells;
implanting selected second regions of the superlattice structure with a second dose of dopants to form emitter, base, and collector terminals of a pair of bipolar junction transistors (BJTs), wherein the second dose is higher than the first dose; and
forming a metallization structure on the emitter, base, and collector terminals of the pair of BJTs.

11. The method of claim 10, wherein implanting the selected first regions comprises implanting one or more wells that separate adjacent BJTs.

12. The method of claim 10, wherein implanting the selected second regions comprises implanting the emitter and collector terminals with p-type dopants to form the pair of BJTs as two P-N-P transistors.

13. The method of claim 10, wherein implanting the selected second regions comprises implanting the emitter and collector terminals with n-type dopants to form the pair of BJTs as two N-P-N transistors.

14. The method of claim 10, forming the metallization structure comprises electrically connecting the pair of BJTs are in a Darlington circuit configuration.

15. A circuit, comprising:
a first bipolar junction transistor (BJT) formed on a superlattice structure, the first BJT having a first base, a first emitter, and a first collector; and
a second BJT formed on the superlattice structure, the second BJT having a second base, a second emitter, and a second collector,
wherein the first emitter is electrically coupled to the second base, and the first and second collectors are electrically coupled to one another.

16. The circuit of claim 15, wherein the superlattice structure is an alternating stack of silicon (Si) and silicon germanium (SiGe) layers.

17. The circuit of claim 15, wherein the first and second BJTs are dual P-N-P type BJTs.

18. The circuit of claim 15, wherein the first and second BJTs are dual N-P-N type BJTs.

19. The circuit of claim 15, wherein the first base is electrically coupled to the first and second collectors.

20. The circuit of claim 15, wherein the emitter, base, and collector regions of the first and second BJTs are within the superlattice structure.
